(19) United States
(12) Patent Application Publication
(10) Pub. No.: US 2015/0162341 A1
(43) Pub. Date: Jun. 11, 2015

(54) NON-VOLATILE MEMORY DEVICE HAVING INCREASED MEMORY CAPACITY

(71) Applicant: SK HYNIX INC., Icheon-si (KR)

(72) Inventor: Seiichi ARITOME, Seongnam-si (KR)

(73) Assignee: SK HYNIX INC., Icheon-si (KR)

(21) Appl. No.: 14/230,619

(22) Filed: Mar. 31, 2014

(30) Foreign Application Priority Data
Dec. 9, 2013 (KR) 10-2013-0152589

(51) Int. Cl. H01L 27/115

(52) U.S. Cl. CPC H01L 27/11582; H01L 27/11556; H01L 27/11529; H01L 27/11573

(57) ABSTRACT

A non-volatile memory device according to an embodiment of the present invention includes a first memory layer including a plurality of memory cells stacked between a first conductive line and a second conductive line over a semiconductor substrate. In addition, a second memory layer including the plurality of memory cells stacked between the second conductive line and a third conductive line. Further, the second memory layer is extended over the page buffer and the peripheral circuit sequentially arranged from the first memory layer.

### CROSS-REFERENCE TO RELATED APPLICATION

The present application claims priority to Korean patent application number 10-2013-0152589 filed Dec. 9, 2013, in the Korean Intellectual Property Office, the entire disclosure of which is incorporated by reference herein.

### TECHNICAL FIELD

Various embodiments relate generally to a non-volatile memory device and, more particularly, to a non-volatile memory device including memory cells stacked in a vertical direction over a substrate.

### BACKGROUND

As the demand for mobile phones, portable memory devices and digital cameras rises, the demand for non-volatile memory devices that are mainly used as memory devices of these products increases. Among non-volatile memory devices, NAND flash memory devices are widely used as data storage devices.

A NAND flash memory device may be classified into a two-dimensional semiconductor device in which strings are formed in a horizontal direction over a semiconductor substrate; and a three-dimensional semiconductor device in which strings are formed in a vertical direction over a semiconductor substrate.

A three-dimensional semiconductor device may be designed to overcome a limitation in increasing a degree of integration of a two-dimensional semiconductor device. The three-dimensional semiconductor device may include a plurality of strings that are formed in a vertical direction over a semiconductor substrate. The plurality of strings may include a drain selection transistor coupled in series between a bit line and a source line, memory cells and a source selection transistor.

### SUMMARY

In accordance with an embodiment, a non-volatile memory device may include a first memory layer including a plurality of memory cells stacked between a first conductive line and a second conductive line over a semiconductor substrate. The non-volatile memory device may also include a second memory layer including a plurality of memory cells stacked between the second conductive line and a third conductive line, and a page buffer and a peripheral circuit sequentially arranged from the first memory layer. Further, the second memory layer is extended over the page buffer and the peripheral circuit.

In accordance with an embodiment, a non-volatile memory device may include a first memory cell array formed over a first memory cell array region of a semiconductor substrate including a page buffer region and a peripheral region. The non-volatile memory device may also include a page buffer unit and peripheral circuits formed over the page buffer region and the peripheral region, respectively. Moreover, the non-volatile memory device may also include a second memory cell array formed over the first memory cell array, the page buffer unit and the peripheral circuits.

In accordance with an embodiment, a non-volatile memory device non-volatile memory device may include a memory layer including a plurality of memory cells stacked between a first conductive line and a second conductive line over a semiconductor substrate. In addition, the non-volatile memory device may also include a page buffer, a peripheral circuit and a pad unit sequentially arranged from the memory layer. First and second metal lines, included in the peripheral circuit and the pad unit, are formed at substantially the same heights as the first conductive line and the second conductive line.

### BRIEF DESCRIPTION OF THE DRAWINGS

FIGS. 1A and 1B are layout views of a non-volatile memory device according to an embodiment;

FIG. 2 is a cross-sectional view illustrating a non-volatile memory device according to an embodiment;

FIG. 3 is a three-dimensional diagram illustrating a memory string shown in FIG. 2;

FIG. 4 is a circuit diagram illustrating a memory string shown in FIG. 2;

FIG. 5 is a cross-sectional view illustrating a non-volatile memory device according to an embodiment;

FIG. 6 is a cross-sectional view illustrating a non-volatile memory device according to an embodiment;

FIG. 7 is a cross-sectional view illustrating a non-volatile memory device according to embodiment;

FIG. 8 is a cross-sectional view illustrating a non-volatile memory device according to an embodiment;

FIG. 9 is a cross-sectional view illustrating a non-volatile memory device according to an embodiment;

FIG. 10 is a schematic block diagram illustrating a memory system according to an embodiment;

FIG. 11 is a schematic block diagram illustrating a fusion memory device or a fusion memory system; and

FIG. 12 is a block diagram illustrating a computing system including a non-volatile memory device.

### DETAILED DESCRIPTION

Hereinafter, various embodiments will be described in detail with reference to the accompanying drawings. The figures are provided to allow those having ordinary skill in the art to understand the scope of the embodiments of the disclosure. The invention may, however, be embodied in different forms and should not be construed as limited to the embodiments set forth herein. Rather, these embodiments are provided so that this disclosure will be thorough and complete, and will fully convey the scope of the invention to those skilled in the art.

Furthermore, “electrically connected/electrically coupled” represents that one component is directly electrically coupled to another component or indirectly electrically coupled through another component. In this specification, a singular form may include a plural form as long as it is not specifically mentioned in a sentence. Furthermore, “include/comprise” or “including/comprising” used in the specification represents that one or more components, steps, operations, and elements exists or are added.

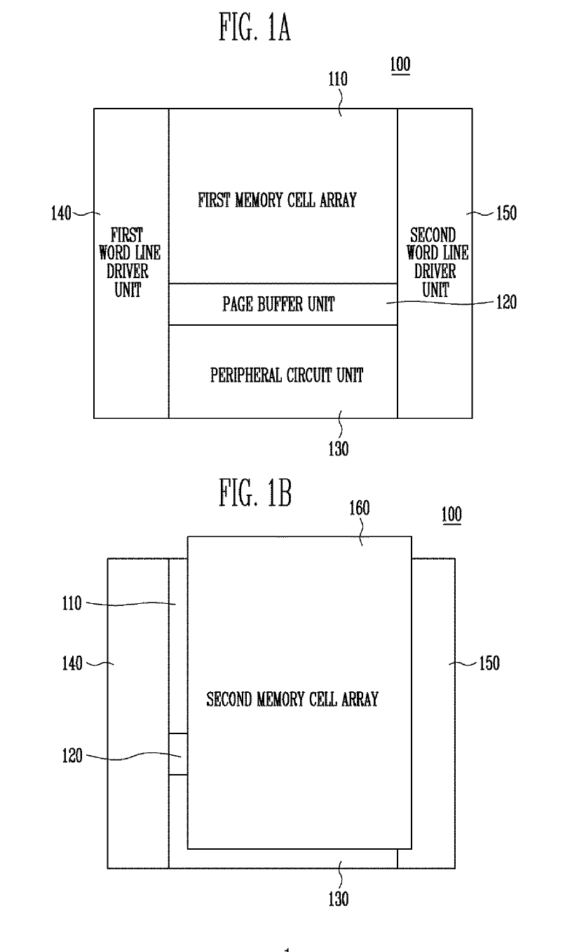

FIGS. 1A and 1B are layout views illustrating a non-volatile memory device according to an embodiment.

Referring to FIGS. 1A and 1B, a non-volatile memory device 100 may include a first memory cell array 110, a page buffer unit 120, a peripheral circuit unit 130, first and second word line driver units 140 and 150 and a second memory cell array 160.

The first memory cell array 110 may include a plurality of memory strings in which a plurality of memory cells are electrically coupled in series with each other. The plurality of memory strings may be electrically coupled between a bit line and source lines.

The page buffer unit 120 may be arranged under the first memory cell array 110 and electrically connected to the bit line of the first memory cell array 110.

The peripheral circuit unit 130 may be arranged under the page buffer unit 120. An oscillator, a charge pump and a controller circuit may be arranged in the peripheral circuit unit 130.

The second memory cell array 160 may be stacked over the first memory cell array 110, the page buffer unit 120 and the peripheral circuit unit 130. Therefore, the second memory cell array 160 may be arranged across a wider area than the first memory cell array 110. In other words, the second memory cell array 160 may include more memory strings than the number of memory strings included in the first memory cell array 110.

The first and second word line driver units 140 and 150 may be arranged at both sides of the first memory cell array 110, the page buffer unit 120 and the peripheral circuit unit 130. The first and second word line driver units 140 and 150 may be electrically coupled to word lines of the first memory cell array 110 and the second memory cell array 160 and apply a driving voltage to these word lines. The first and second word line driver units 140 and 150 may extend from both sides of the first memory cell array 110 to both sides of the page buffer unit 120 and the peripheral circuit unit 130.

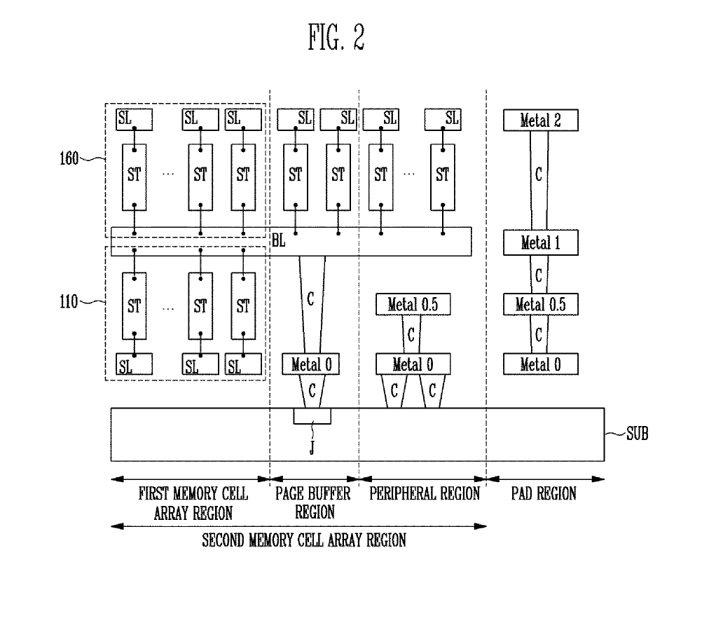

FIG. 2 is a cross-sectional view illustrating a non-volatile memory device according to an embodiment.

Referring to FIG. 2, the first memory cell array 110 and the second memory cell array 160 may be sequentially stacked over a semiconductor substrate SUB in which a first memory cell array region, a page buffer region, a peripheral region and a pad region are defined and sequentially arranged. A second memory cell array region may include the first memory cell array region, the page buffer region and the peripheral region sequentially arranged.

The first memory cell array 110 may be arranged over the first memory cell array region of the semiconductor substrate SUB and include a plurality of memory strings ST. The plurality of memory strings ST may be electrically connected in a vertical direction between a bit line BL and source lines SL. The bit line BL may be shared by the first memory cell array 110 and the second memory cell array 160 by extending the bit line BL to the first memory cell array region, the page buffer region and the peripheral region. A structure of the memory string will be described below.

A page buffer circuit (not illustrated) may be arranged in the page buffer region and electrically connected to the bit line BL of the first and second memory cell arrays 110 and 160. The page buffer unit 120 may formed over the page buffer region. Contacts C and a metal line Metal 0 may be formed in the page buffer region in order to electrically connect the bit line BL and a junction J in the semiconductor substrate SUB. The metal line Metal 0 may be formed at the same time as the source lines SL of the first memory cell array 110 are formed. Therefore, the metal line Metal 0 and the source lines SL may be formed at substantially the same height as each other.

A plurality of peripheral circuits that include an oscillator, a pump and a controller circuit (which are not illustrated) may be formed in the peripheral region. The peripheral circuit unit 130 may be formed over the peripheral region. A plurality of metal lines Metal 0 and Metal 0.5 and a plurality of plurality of contacts C may be formed to electrically connect individual elements included in these circuits. The metal line Metal 0 may be formed at the same time as the source lines SL of the first memory cell array 110 are formed. The metal line Metal 0.5 may be formed between the metal line Metal 0 and the bit line BL in order to prevent an electrical contact therebetween. Therefore, the metal line Metal 0 and the source lines SL may be formed at substantially the same height as each other.

A plurality of metal lines Metal 0, Metal 0.5, Metal 1 and Metal 2 and a plurality of contacts C may be formed in the pad region. The metal lines Metal 0, Metal 0.5, Metal 1 and Metal 2 may be provided in order to form pads so that the pads may be electrically coupled to the metal lines electrically coupled to the plurality of circuits formed in the page buffer region and the peripheral region.

The second memory cell array 160 may be formed in the second memory cell array region that includes the first memory cell array region, the page buffer region and the peripheral region of the semiconductor substrate SUB. More specifically, the second memory cell array 160 may be formed over the first memory cell array 110, page buffers (not illustrated); and peripheral circuits (not illustrated) that are formed in the peripheral region and may include a plurality of memory strings ST. The plurality of memory strings ST may be electrically connected in the vertical direction and have a vertical channel structure between the bit line BL and another set of the source lines SL. More specifically, the source lines SL in the first memory cell array 110 are the first conductive line; and the other set of source lines SL in the second memory cell array 160 are the third conductive line. The bit line BL may be the second conductive line. The first memory cell array 110 and the second memory cell array 160 may share the bit line BL by extending the bit line BL to the first memory cell array region, the page buffer region and the peripheral region.

According to an embodiment, since the second memory cell array 160 is arranged over the first memory cell array 110 and extended to the page buffer region and the peripheral region, more memory cells may be formed. As a result, memory capacity of a non-volatile memory device may be improved.

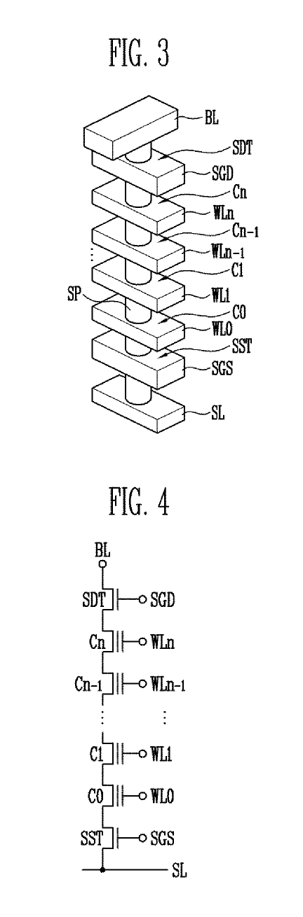

FIG. 3 is a three-dimensional view illustrating the memory string shown in FIG. 2. FIG. 4 is a circuit diagram illustrating the memory string shown in FIG. 2.

Referring to FIGS. 3 and 4, a common source line SL may be formed on a semiconductor substrate, and a vertical channel layer SP may be formed on the common source line SL. A top portion of the vertical channel layer SP may be electrically connected to the bit line BL. The vertical channel layer SP may include polysilicon. Conductive layers SGS, WL0 to WLn, and SGD may be formed to surround the vertical channel layer SP at different heights. A multilayer (not illustrated) that includes a charge storage layer may be formed over a surface of the vertical channel layer SP. The multilayer may also be located between the vertical channel layer SP and the conductive layers SGS, WL0 to WLn and SGD.

The lowermost conductive layer may be configured as a source selection line (or first selection line) SGS, and the uppermost conductive layer may be configured as a drain selection line (or second selection line) SGD. The remaining conductive layers between the selection lines SGS and SGD may be configured as word lines WL0 to WLn. In other words, the conductive layers SGS, WL0 to WLn, and SGD may be formed in a plurality of layers over the semiconductor substrate. The vertical channel layer SP that passes through the conductive layers SGS, WL0 to WLn, and SGD may be electrically connected in the vertical direction between the bit line BL and the source line SL formed over the semiconductor substrate.

A drain selection transistor (or second selection transistor) SDT may be formed at a position where the uppermost conductive layer SGD surrounds the vertical channel layer SP. A source selection transistor (or first selection transistor) SST may be formed at a position where the lowermost conductive layer SGS surrounds the vertical channel layer SP. Memory cells C0 to Cn may be formed at positions where intermediate conductive layers WL0 to WLn cover the vertical channel layer SP.

The memory string having the above-described structure may include the source selection transistor SST, the memory cells C0 to Cn and the drain selection transistor SDT that are electrically connected in the vertical direction between the common source line SL and the bit line BL. The source selection transistor SST may electrically connect the memory cells C0 to Cn to the common source line SL in response to a first selection signal applied to the first selection line SGS. The drain selection transistor SDT may electrically connect the memory cells C0 to Cn to the bit line BL in response to a second selection signal applied to the second selection line SGD.

FIG. 5 is a cross-sectional view illustrating a non-volatile memory device according to an embodiment.

Referring to FIG. 5, the first memory cell array 110 and the second memory cell array 160 may be sequentially stacked over the semiconductor substrate SUB in which a first memory cell array region, a page buffer region, a peripheral region and a pad region are defined. A second memory cell array region may include the first memory cell array region, page buffer region and the peripheral region.

The first memory cell array 110 may be arranged over the first memory cell array region of the semiconductor substrate SUB and include the memory strings ST. In addition, the first memory cell array 110 may include a two-layer structure. In other words, the first memory cell array 110 may include a group of memory strings ST, which are electrically connected in the vertical direction between source lines SL0 and a first bit line BLA; and a group of memory strings ST, which are electrically connected in the vertical direction between the first bit line BL and source lines SL1. These two groups may be stacked on top of each other. The first memory cell array 110 and the second memory cell array 160 may share source lines SL1 by extending the source lines SL1 to the first memory cell array region, the page buffer region and the peripheral region. The source lines SL2 and a second bit line BLB may also extend to the first memory cell array region, the page buffer region and the peripheral region. The structure of each memory string may be the same as described above in FIGS. 2 and 3.

A page buffer circuit (not illustrated) may be arranged in the page buffer region. The page buffer circuit may be electrically coupled to the first bit line BLA of the first memory cell array 110 and a second bit line BLB of the second memory cell array 160. Therefore, in the page buffer region, the contacts C and the metal line Metal 2 may be formed to electrically connect the first and second bit lines BLA and BLB; and the contacts C and the metal line Metal 0 may be formed to electrically connect the first bit line BLA and the junction J in the semiconductor substrate SUB. The metal line Metal 0 may be formed at the same time as the source lines SL0 of the first memory cell array 110 are formed. The metal line Metal 2 may be formed at the same time as the source lines SL1, shared by the first memory cell array 110 and the second memory cell array 160, are formed. Therefore, the metal line Metal 0 and the source lines SL0 may be formed at substantially the same height, and the metal line Metal 2 and the source lines SL1 may be formed at substantially the same height. The metal line Metal 2 and a contact C may be arranged to electrically connect the first and second bit lines BLA and BLB.

A plurality of peripheral circuits that include an oscillator, a pump and a controller circuit (which are not illustrated) may be formed in the peripheral region. The metal lines Metal 0 and Metal 1 and the contacts C may be formed. The metal line Metal 0 may be formed at the same time as the source lines SL0 of the first memory cell array 110 are formed. The metal line Metal 1 may be formed at the same time as the first bit line BLA is formed. Therefore, the metal line Metal 0 may be formed at substantially the same height as the source lines SL0, and the metal line Metal 1 may be formed at substantially the same height as the first bit line BLA.

A plurality of metal lines Metal 0, Metal 1, Metal 2, Metal 3 and Metal 4 and a plurality of contacts C may be formed in the pad region in order to form pads so that the pads may be electrically coupled to the circuits formed in the page buffer region and the peripheral region.

The second memory cell array 160 may be formed in the second memory cell array region that includes the first memory cell array region, the page buffer region and the peripheral region of the semiconductor substrate SUB. More specifically, the second memory cell array 160 may be arranged over the first memory cell array 110, page buffers (not illustrated), and peripheral circuits (not illustrated) formed over the peripheral region and may include the memory strings ST. In addition, the second memory cell array 160 may have a two-layer structure. In other words, the second memory cell array 160 may include a group of memory strings ST, which are electrically connected in the vertical direction between the source lines SL1 and the second bit line BLB; and a group of memory strings ST, which are electrically connected in the vertical direction between the second bit line BLB and source lines SL2. These two groups may be stacked on top of each other. Portions of the source lines SL1 may be shared between the first second memory cell arrays 110 and 160.

According to an embodiment, since the first and second memory cell arrays 110 and 160 are formed in a two-layer structure, memory capacity may be improved. Since the second memory cell array 160 having the two-layer structure is formed over the first memory cell array 110 and extended to the page buffer region and the peripheral region, more memory cells may be formed. Accordingly, memory capacity of a non-volatile memory device may be improved.

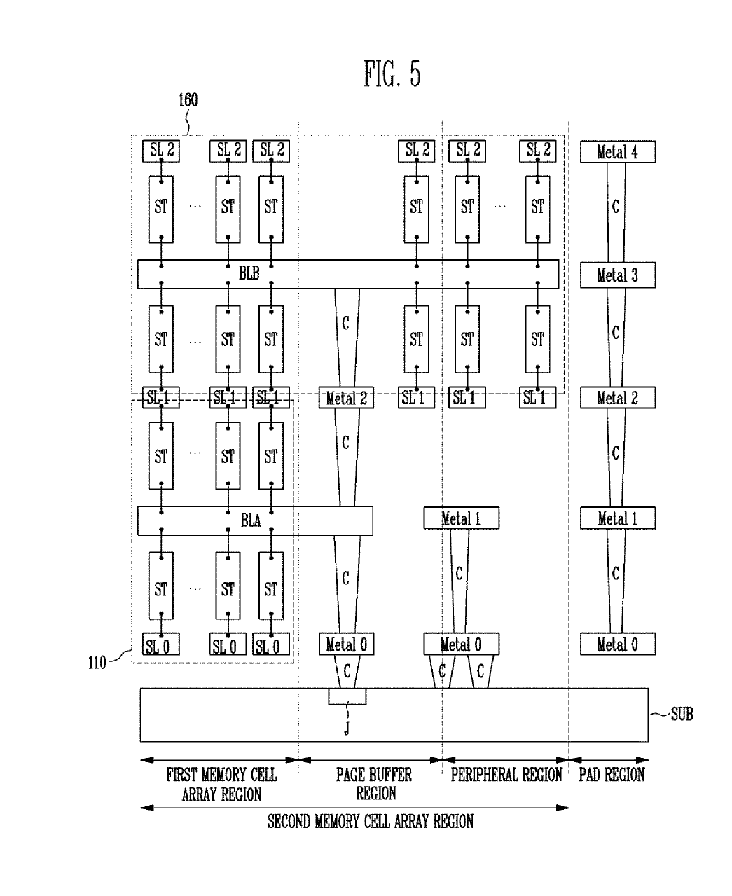

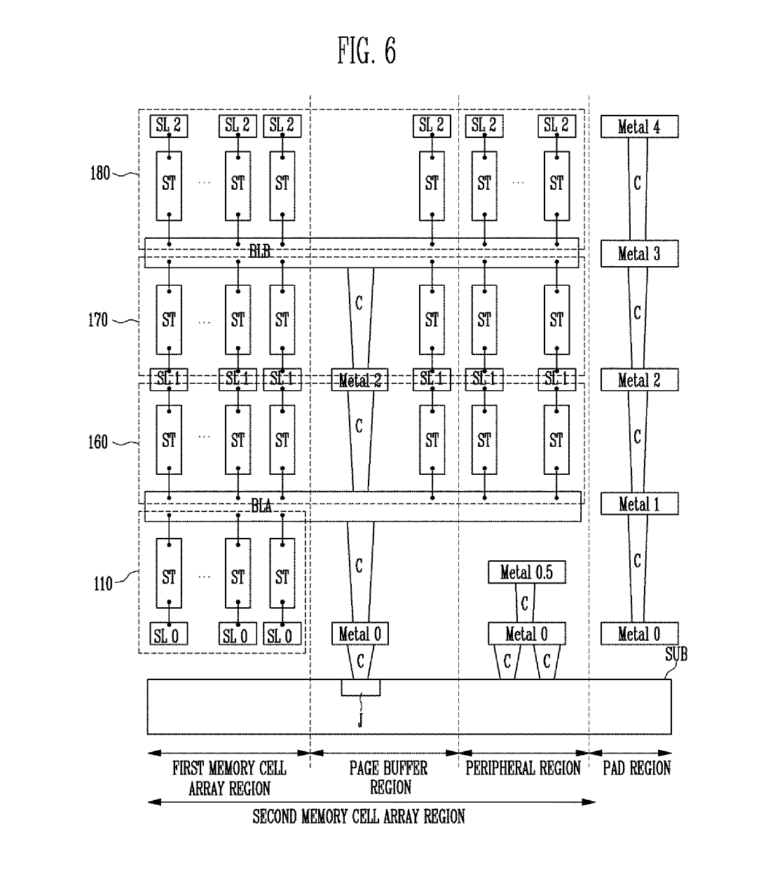

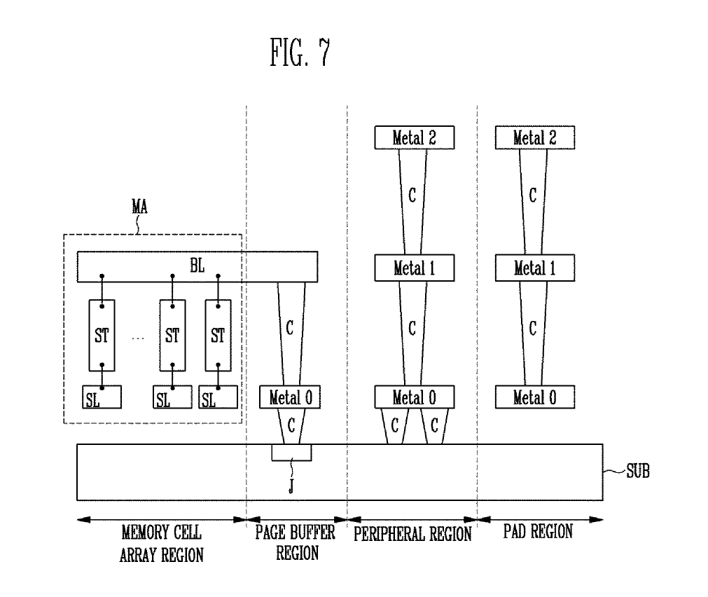

FIG. 6 is a cross-sectional view illustrating a non-volatile memory device according to an embodiment.

Referring to FIG. 6, the first memory cell array 110, the second memory cell array 160, a third memory cell array 170; and a fourth memory cell array 180 may be sequentially stacked over the semiconductor substrate SUB in which a first memory cell array region, a page buffer region, a peripheral region and a pad region are defined. A second memory cell array region may include the first memory cell array region, the page buffer region and the peripheral region.

The first memory cell array 110 may be formed over the first memory cell array region of the semiconductor substrate SUB and include the memory strings ST. The first memory cell array 110 may include the memory strings ST that are electrically coupled in the vertical direction between the source lines SL0 and the first bit line BLA. The first bit line BLA may be shared by the first and second memory cell arrays 110 and 160 by extending the first bit line BLA to the first memory cell array region, the page buffer region and the peripheral region. The memory strings ST of the second memory cell array 160 may also extend to the first memory cell array region, the page buffer region and the peripheral region. The structure of each memory string may be substantially the same as described in FIGS. 2 and 3.

A page buffer circuit (not illustrated) may be arranged in the page buffer region. The page buffer circuit may be electrically coupled to the first bit line BLA of the first and second memory cell arrays 110 and 160 and the second bit line BLB of the third and fourth memory cell arrays 170 and 180. In the page buffer region, the contacts C and the metal line Metal 2 that electrically connect the first and second bit lines BLA and BLB may be formed; and the contacts C and the metal line Metal 0 that electrically connect the first bit line BLA and the junction J in the semiconductor substrate SUB may be formed. The metal line Metal 0 may be formed at the same time as the source lines SL0 of the first memory cell array 110 are formed. The metal line Metal 2 may be formed at the same time as the source lines SL1, shared by the second memory cell array 160 and the third memory cell array 170, are formed. Therefore, the metal line Metal 0 may be formed at substantially the same height as the source lines SL0; and the metal line Metal 2 may be formed at substantially the same height as the source lines SL1.

A plurality of peripheral circuits that include an oscillator, a pump and a controller circuit (which are not illustrated) may be formed in the peripheral region. A plurality of metal lines Metal 0 and Metal 0.5 and a plurality of plurality of contacts C may be formed to electrically connect individual elements included in these circuits. The metal line Metal 0 may be formed at the same time as the source lines SL0 of the first memory cell array 110 are formed. The metal line Metal 0.5 may be formed between the metal line Metal 0 and the bit line BLA in order to prevent an electrical contact therebetween. Therefore, the metal line Metal 0 and the source lines SL0 may be formed at substantially the same height.

The metal lines Metal 0, Metal 1, Metal 2, Metal 3 and Metal 4 and the contacts C may be formed in the pad region in order to form pads so that the pads may be electrically coupled to the metal lines electrically coupled to the circuits formed in the page buffer region and the peripheral region. The metal line Metal 3 may be formed at substantially the same height as the second bit line BLB.

The second memory cell array 160 may be formed over the second memory cell array region including the first memory cell array region, the page buffer region and the peripheral region of the semiconductor substrate SUB. More specifically, the second memory cell array 160 may be arranged over the first memory cell array 110, page buffers (not illustrated) and peripheral circuits (not illustrated) of the peripheral region and may include the memory strings ST. The memory strings ST may be electrically connected in the vertical direction between the first bit line BLA and the source lines SL1. The first bit line BLA may be shared by the first memory cell array 110 and the second memory cell array 160 by extending the first bit line BLA to the first memory cell array region, the page buffer region and the peripheral region. In addition, the source lines SL1 may be shared by the second memory cell array 160 and the third memory cell array 170 by extending the source lines SL1 to the first memory cell array region, the page buffer region and the peripheral region. The third memory cell array 170 may be formed between the source lines SL1 and second bit line BLB.

The third memory cell array 170 may include the memory strings ST and be stacked over the second memory cell array 160. In other words, the third memory cell array 170 may be formed over the second memory cell array region that includes the first memory cell array region, the page buffer region and the peripheral region of the semiconductor substrate SUB. The memory strings ST may be electrically coupled in the vertical direction between the second bit line BLB and the source lines SL1. The source lines SL1 may be shared by the third memory cell array 170 and the second memory cell array 160 by extending the source lines SL1 to the first memory cell array region, the page buffer region and the peripheral region.

The fourth memory cell array 180 may include the memory strings ST and be stacked over the third memory cell array 170. In other words, the fourth memory cell array 180 may be arranged over the second memory cell array region including the first memory cell array region, the page buffer region and the peripheral region semiconductor substrate SUB. The memory strings ST may be electrically coupled in the vertical direction between the second bit line BLB and the source lines SL2. The second bit line BLB may be shared by the third memory cell array 170 and the fourth memory cell array 180 by extending the second bit line BLB to the first memory cell array region, the page buffer region and the peripheral region.

According to an embodiment, since the first to fourth memory cell arrays 110, 160, 170 and 180 are sequentially stacked, more memory cells may be stacked within a fixed area. As a result, memory capacity may be improved. In addition, since the second, third and fourth memory cell arrays 160, 170 and 180 are arranged over the first memory cell array 110 and extended to the page buffer region and the peripheral region, more memory cells may be formed. Therefore, the memory capacitance of the non-volatile memory device may be improved.

FIG. 7 is a cross-sectional view illustrating a non-volatile memory device according to an embodiment.

Referring to FIG. 7, a memory cell array MA may be formed over a memory cell array of the semiconductor substrate SUB in which a memory cell array region, a page buffer region, a peripheral region and a pad region are defined. The memory cell array MA may include a plurality of memory strings ST that are formed in the vertical direction over the semiconductor substrate SUB. The plurality of memory strings ST may be electrically coupled in the vertical direction between the bit line BL and the source lines SL. The bit line BL may be extended to the page buffer region so that the bit line BL may be electrically connected to page buffers (not illustrated) formed in the page buffer region. The structure of each memory string may be substantially the same as described above with reference to FIGS. 2 and 3.

A page buffer circuit (not illustrated) may be arranged in the page buffer region and electrically connected to the bit line BL of the memory cell array MA. The contacts C and the metal line Metal 0 may be formed in the page buffer region to electrically connect the bit line BL and the junction J in the semiconductor substrate SUB. The metal line Metal 0 may be formed at the same time as the source lines SL of the memory cell array MA are formed. Therefore, the metal line Metal 0 may be formed at substantially the same height as the source lines SL.

A plurality of peripheral circuits that include an oscillator, a pump and a controller circuit (which are not illustrated) may be formed in the peripheral region. The metal lines Metal 0, Metal 1 and Metal 2 and the contacts C may be formed to electrically connect individual elements included in these circuits. The metal line Metal 0 may be formed at the same time as the source lines SL of the memory cell array MA are formed. The metal line Metal 1 may be formed at the same time as the bit line BL is formed. Therefore, the metal line Metal 0 may be formed at substantially the same height as the source lines SL.

The metal lines Metal 0, Metal 1 and Metal 2 and the contacts C may be formed in the pad region. The metal lines Metal 0, Metal 1 and Metal 2 may be provided to form pads so that the pads may be electrically coupled to the metal lines electrically coupled to the plurality of circuits formed in the page buffer region and the peripheral region. The metal line Metal 0 may be formed at the same time as the source lines SL of the memory cell array MA, the metal line Metal 0 of the page buffer region and the metal line Metal 0 of the peripheral region are formed. The metal line Metal 1 may be formed at the same time as the bit line BL of the memory cell array MA, the metal line Metal 1 of the page buffer region and the metal line Metal 1 of the peripheral region are formed. Therefore, the metal line Metal 0 may be formed at substantially the same height as the source lines SL, and the metal line Metal 1 may be formed at substantially the same height as the bit line BL.

According to an embodiment, since metal lines formed in a peripheral region and a pad region are formed at the same time as a source line and a bit line are formed in a memory cell array region, the number of manufacturing processes may be reduced, and the manufacturing processes may become easy.

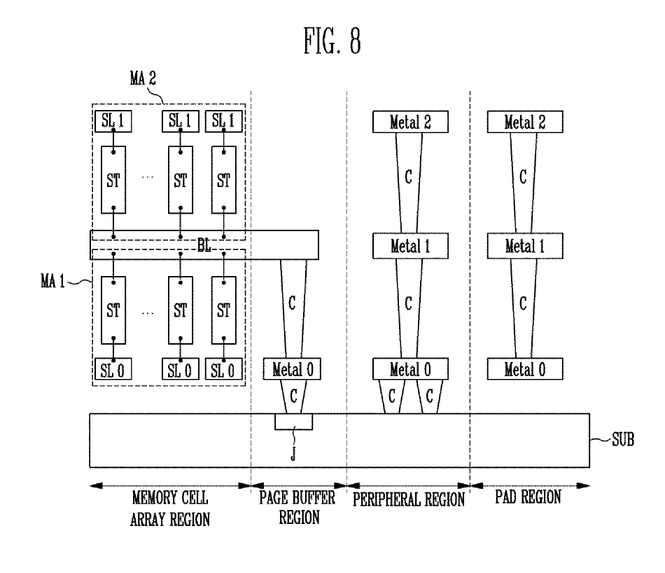

FIG. 8 is a cross-sectional view illustrating a non-volatile memory device according to an embodiment.

Referring to FIG. 8, first and second memory cell arrays MA1 and MA2 may be stacked over the semiconductor substrate SUB in which a memory cell array region, a page buffer region, a peripheral region and a pad region are defined. The first and second memory cell arrays MA1 and MA2 may include the memory strings ST that are formed in the vertical direction over the semiconductor substrate SUB. The memory strings ST of the first memory cell array MA1 may be formed between the source lines SL0 and the bit line BL. The memory strings ST of the second memory cell array MA2 may be formed between the source lines SL1 and the bit line BL. The bit line BL may be extended to the page buffer region so that the bit line BL may be electrically connected to a page buffer (not illustrated) formed in the page buffer region. The structure of each memory string may be substantially the same as described above with reference to FIGS. 2 and 3.

A page buffer circuit (not illustrated) may be arranged in the page buffer region and electrically connected to the bit line BL. The contacts C and the metal line Metal 0 may be formed in the page buffer region to electrically connect the bit line BL and the junction J in the semiconductor substrate SUB. The metal line Metal 0 may be formed at the same time as the source lines SL0 of the first memory cell array MA1 are formed. Therefore, the metal line Metal 0 may be formed at substantially the same height as the source lines SL0.

A plurality of peripheral circuits may be formed in the peripheral region. The metal lines Metal 0, Metal 1 and Metal 2 and the contacts C may be formed to electrically connect individual elements included in these circuits. The metal line Metal 0 may be formed at the same time as the source lines SL0 of the memory cell array MA are formed. The metal line Metal 1 may be formed at the same time as the bit line BL is formed. The metal line Metal 2 may be formed at the same time as the source lines SL1 of the second memory cell array MA2 are formed. Therefore, the metal line Metal 0 may be formed at substantially the same height as the source lines SL.

The metal lines Metal 0, Metal 1 and Metal 2 and the contacts C may be formed in the pad region. The metal lines Metal 0, Metal 1 and Metal 2 may be provided to form pads so that the pads may be electrically coupled to the metal lines electrically coupled to the plurality of circuits formed in the page buffer region and the peripheral region. The metal line Metal 0 may be formed at the same time as the source lines SL0 of the first memory cell array MA1 are formed. The metal line Metal 1 may be formed at the same time as the bit line BL is formed. In addition, the metal line Metal 2 may be formed at the same time as the source lines SL1 of the second memory cell array MA2 are formed. Therefore, the metal line Metal 0 may be formed at substantially the same height as the source lines SL0. The metal line Metal 1 may be formed at substantially the same height as the bit line BL. In addition, the metal line Metal 2 may be formed at substantially the same height as the source lines SL1.

According to an embodiment, since metal lines are formed in a peripheral region and a pad region at the same time as a source line and a bit line are formed in a memory cell array region, the number of manufacturing processes may be reduced, and the manufacturing processes may become easy.

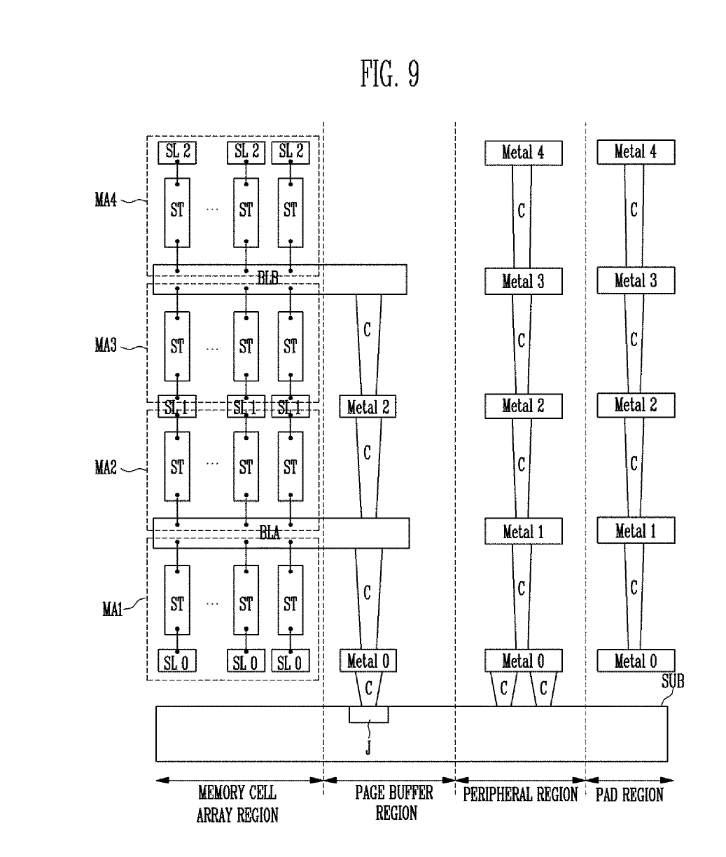

FIG. 9 is a cross-sectional view illustrating a non-volatile memory device according to an embodiment.

Referring to FIG. 9, first to fourth memory cell arrays MA1 to MA4 may be stacked over a memory cell array of the semiconductor substrate SUB in which a memory cell array region, a page buffer region, a peripheral region and a pad region are defined. The first to fourth memory cell arrays MA1 to MA4 may include a plurality of memory strings ST that are formed in the vertical direction over the semiconductor substrate SUB. The plurality of memory strings ST of the first memory cell array MA1 may be formed between the source lines SL0 and the first bit line BLA. The memory strings ST of the second memory cell array MA2 may be formed between the source lines SL1 and the first bit line BLA. In addition, the memory strings ST of the third memory cell array MA3 may be formed between the source lines SL1 and the second bit line BLB. The memory strings ST of the fourth memory cell array MA4 may be formed between the source line SL2 and the second bit line BLB.

The first and second bit lines BLA and BLB may be extended to the page buffer region so that the first and second bit lines BLA and BLB may be electrically connected to a page buffer (not illustrated) formed in the page buffer region. The structure of each memory string may be substantially the same as described above with reference to FIGS. 2 and 3.

A page buffer circuit (not illustrated) may be arranged in the page buffer region and electrically connected to the first and second bit lines BLA and BLB. In the page buffer region, the metal line Metal 2 and the contacts C may be formed to electrically connect the first bit line BLA and the second bit line BLB; and the contacts C and the metal line Metal 0 may be formed to electrically connect the junction J in the semiconductor substrate SUB and the first bit line BLA. The metal line Metal 0 may be formed at the same time as the source lines SL0 of the first memory cell array MA1 are formed. The metal line Metal 2 may be formed at the same time as the source lines SL1 of the second and third memory cell arrays MA2 and MA3. Therefore, the metal line Metal 0 may be formed at substantially the same height as the source lines SL0, and the metal line Metal 2 may be formed at substantially the same height as the source lines SL1.

A plurality of peripheral circuits that include an oscillator, a pump and a controller circuit (which are not illustrated) may be formed in the peripheral region. The metal lines Metal 0, Metal 1, Metal 2, Metal 3 and Metal 4 and the contacts C may be formed. The metal line Metal 0 may be formed at the same time as the source lines SL0 of the first memory cell array MA1 are formed. The metal line Metal 1 may be formed at the same time as the first bit line BLA is formed. The metal line Metal 2 may be formed at the same time as the source lines SL1 of the second memory cell array MA2 are formed. In addition, the metal line Metal 3 may be formed at the same time as the second bit line BLB is formed. The metal line Metal 4 may be formed at the same time as the source lines SL2 of the fourth memory cell array MA4 are formed. Therefore, the metal line Metal 0 may be formed at substantially the same height as the source lines SL0. The metal line Metal 1 may have substantially the same height as the first bit line BLA. In addition, the metal line Metal 2 may be formed at substantially the same height as the source lines SL1; the metal line Metal 3 may be formed at substantially the same height as the second bit line BLB; and the metal line Metal 4 may be formed at substantially the same height as the source line SL2.

The metal lines Metal 0, Metal 1, Metal 2, Metal 3 and Metal 4 and the contacts C may be formed in the pad region in order to form pads so that the pads may be electrically coupled to the metal lines electrically coupled to the circuits formed in the page buffer region and the peripheral region. The metal line Metal 0 may be formed at the same time as the source lines SL0 of the first memory cell array MA1 are formed. The metal line Metal 1 may be formed at the same time as the first bit line BLA is formed. The metal line Metal 2 may be formed at the same time as the source lines SL1 of the second memory cell array MA2 are formed. In addition, the metal line Metal 3 may be formed at the same time as the second bit line BLB is formed. The metal line Metal 4 may be formed at the same time as the source lines SL2 of the fourth memory cell array MA4 are formed. Therefore, the metal line Metal 0 may be formed at substantially the same height as the source lines SL0, and the metal line Metal 1 may have the same height as the first bit line BLA. In addition, the metal line Metal 2 may be formed at substantially the same height as the source lines SL1; the metal line Metal 3 may be formed at substantially the same height as the second bit line BLB; and the metal line Metal 4 may be formed at substantially the same height as the source line SL2.

According to an embodiment, since metal lines are formed in a peripheral region and a pad region at the same time as a source line and a bit line are formed in a memory cell array region; the number of processes may be reduced; and the manufacturing processes may become easy.

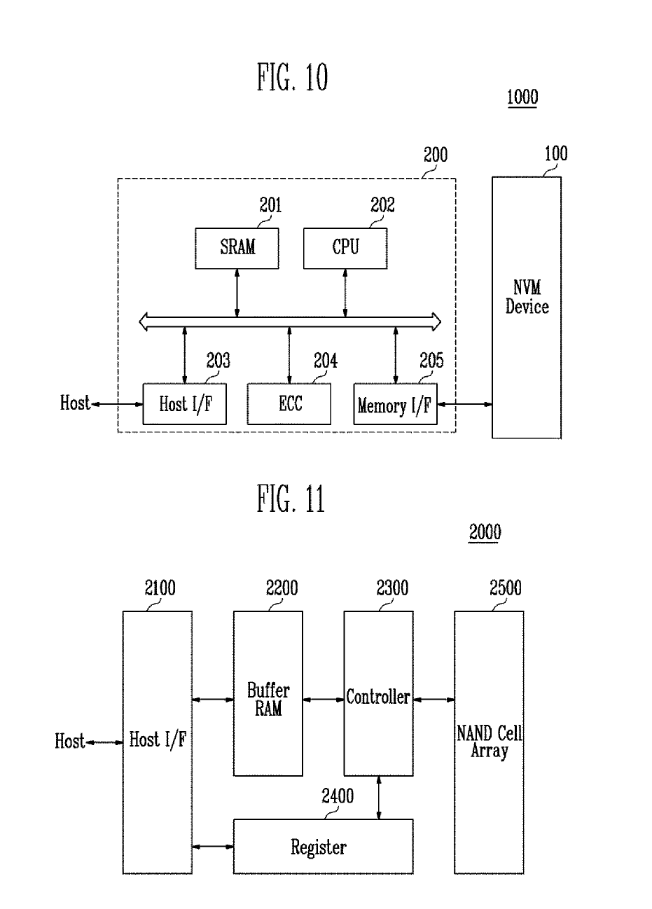

FIG. 10 is a schematic block diagram illustrating a memory system according to an embodiment.

As illustrated in FIG. 10, a memory system 1000 according to an embodiment may include a non-volatile memory device 100 and a memory controller 200.

The non-volatile memory device 100 may include the above-described semiconductor memory device and operate according to the above-described method for the compatibility with the memory controller 200. The memory controller 200 may be suitable for controlling the non-volatile memory device 100. The memory controller 200 may be a solid state disk (SSD) or a memory card in which the non-volatile memory device 100 and the memory controller 200 are combined. SRAM 201 may function as an operation memory of a processing unit or CPU 202. A host interface 203 may include a data exchange protocol of a host being electrically coupled to the memory system 100. An error correction block 204 may detect and correct errors included in a data read from the non-volatile memory device 100. A memory interface 205 may interface with the non-volatile memory device 100. The processing unit 202 may perform the general control operation for data exchange of the memory controller 200.

Though not shown in FIG. 10, the memory system 1000 may further include ROM (not illustrated) that stores code data to interface with the host. In addition, the non-volatile memory device 100 may be a multi-chip package composed of a plurality of flash memory chips. The memory system 1000 having the above-described configuration may be provided as a storage medium having high reliability and low error rate. When a flash memory device according to an embodiment is provided in a memory system such as a semiconductor disk device (solid state disk (SSD)) on which research has been actively conducted, the memory controller 110 may communicate with an external device (e.g., a host) through one of various interface protocols, such as USB, MMC, PCI-E, SATA, PATA, SCSI, ESDI and IDE.

FIG. 11 is a schematic block diagram illustrating a fusion memory device or a fusion memory system performing a program operation according to the earlier described embodiments. For example, technical features of the invention may be applied to a OneNAND flash memory device 2000 as a fusion memory device.

The OneNand flash memory device 2000 may include a host interface (I/F) 2100, a buffer RAM 2200, a controller 2300, a register 2400 and a NAND flash cell array 2500. The host interface 2100 may be suitable for exchanging various types of information with a device using different protocols. The buffer RAM 2200 may be loaded with codes for driving the memory device or temporarily store data. The controller 2300 may be suitable for controlling read and program operations and every state in response to a control signal and a command that are externally given. The register 2400 may be configured to store data including instructions, addresses and configurations defining a system operating environment in the memory device. The NAND flash cell array 2500 may include operating circuits including non-volatile memory cells and page buffers. In response to a write request from a host, the OneNAND flash memory device 2000 may program data in the aforementioned manner.

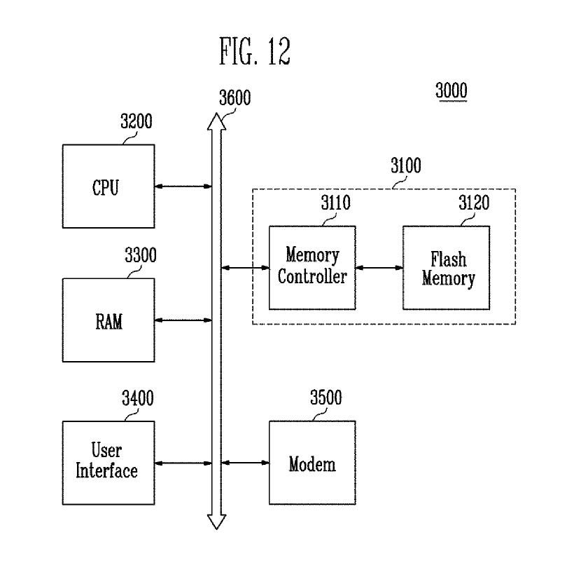

FIG. 12 is a schematic view illustrating a computing system including a flash memory device 3120.

A computing system 3000 according to an embodiment may include a microprocessor or CPU 3200, RAM 3300, a user interface 3400, a modem 3500, such as a baseband chipset, a memory controller 3110 and a memory system 3100 that are electrically coupled to a system bus 3600. In addition, when the computing system 3000 is a mobile device, a battery (not illustrated) may be further included to apply an operating voltage to the computing system 3000. Though not shown in FIG. 12, the computing system 3000 may further include application chipsets, a camera image processor (CIS) and mobile DRAM. The memory system 3100 may form a solid state drive/disk (SSD) that uses a non-volatile memory device in order to store data. Alternatively, the memory system 3100 may be provided as a fusion memory flash memory (e.g., OneNAND flash memory).

It will be apparent to those skilled in the art that the above embodiments of the invention may be implemented by a program or a recording medium, in which the program is recorded; configured to perform functions corresponding to the constitution of the embodiments; as well as the device and method disclosed herein.

Although the invention has been described with reference to certain embodiments thereof, it will be understood by those skilled in the art that a variety of modifications and variations may be made to the invention without departing from the spirit or scope of the invention defined in the appended claims, and their equivalents.

What is claimed is:

1. A non-volatile memory device, comprising:
a first memory layer including a plurality of memory cells stacked between a first conductive line and a second conductive line over a semiconductor substrate;
a second memory layer including a plurality of memory cells stacked between the second conductive line and a third conductive line; and
a page buffer and a peripheral circuit sequentially arranged from the first memory layer,
wherein the second memory layer is extended over the page buffer and the peripheral circuit.

2. The non-volatile memory device of claim 1, wherein the second conductive line and the third conductive line are extended over the page buffer and the peripheral circuit.

3. The non-volatile memory device of claim 1, wherein the first conductive line and the third conductive line are source lines, and the second conductive line is a bit line.

4. The non-volatile memory device of claim 1, further comprising:
first and second word line driver units formed at both sides of the first memory layer, the page buffer and the peripheral circuit.

5. The non-volatile memory device of claim 1, wherein the first memory layer and the second memory layer include a plurality of memory strings including the plurality of memory cells, and the plurality of memory strings have a vertical channel structure.

6. A non-volatile memory device, comprising:
a first memory cell array formed over a first memory cell array region of a semiconductor substrate including a page buffer region and a peripheral region;
a page buffer unit and peripheral circuits formed over the page buffer region and the peripheral region, respectively; and
a second memory cell array formed over the first memory cell array, the page buffer unit and the peripheral circuits.

7. The non-volatile memory device of claim 6, wherein the first memory cell array and the second memory cell array include a plurality of memory strings having a vertical channel structure.

8. The non-volatile memory device of claim 6, wherein the first memory cell array includes first memory strings formed between the first source line and the first bit line and second memory strings formed between the first bit line and a second source line.

9. The non-volatile memory device of claim 8, wherein the second memory cell array includes third memory strings formed between the second source line and a second bit line and fourth memory strings formed between the second bit line and a third source line.

10. The non-volatile memory device of claim 9, wherein the second source line, the second bit line and the third source line are extended to the first memory cell array region, the page buffer region and the peripheral region.

11. The non-volatile memory device of claim 8, wherein the first bit line is extended to the first memory cell array region, the page buffer region and the peripheral region, and a second memory cell string is extended to the first memory cell array region, the page buffer region and the peripheral region.

12. The non-volatile memory device of claim 9, wherein in the page buffer region, a first metal line and a first contact are formed to electrically connect the first bit line and the page buffer, and a second metal line and a second contact are arranged to electrically connect the first and second bit lines.

13. The non-volatile memory device of claim 12, wherein the first metal line is arranged at substantially the same height as the first source line, and the second metal line is arranged at substantially the same height as the second source line.

14. The non-volatile memory device of claim 12, wherein in the peripheral region, a third metal line is formed at substantially the same position as the first metal line, and a fourth metal line is formed at a height between the first bit line and the first metal line.

15. The non-volatile memory device of claim 6, wherein the first memory cell array region, the page buffer region and the peripheral region are sequentially arranged.

16. The non-volatile memory device of claim 6, further comprising:
first and second driver units formed at both sides of the first memory cell array, the page buffer unit and the peripheral circuits.

17. A non-volatile memory device, comprising:
a memory layer including a plurality of memory cells stacked between a first conductive line and a second conductive line over a semiconductor substrate; and
a page buffer, a peripheral circuit and a pad unit sequentially arranged from the memory layer,
wherein first and second metal lines, included in the peripheral circuit and the pad unit, are formed at substantially the same heights as the first conductive line and the second conductive line.

18. The non-volatile memory device of claim 17, further comprising:
an upper memory layer formed between the second conductive line and a third conductive line.

19. The non-volatile memory device of claim 18, wherein the third metal line, included in the peripheral circuit and the pad unit, is formed at substantially the same height as the third conductive line of the upper memory layer.

20. The non-volatile memory device of claim 18, wherein the memory layer and the upper memory layer include a plurality of memory strings including the plurality of memory cells, and the plurality of memory strings have a vertical channel structure.
